(19) United States
(12) Patent Application Publication
(10) Pub. No.: US 2007/0252226 A1
(43) Pub. Date: Nov. 1, 2007

(54) IMAGE DISPLAY DEVICE

(76) Inventors: Hae-Su Youn, Yongin-si (KR); Soon-Cheol Shin, Yongin-si (KR); Kuen-Dong Ha, Yongin-si (KR); Jong-Hoon Lim, Yongin-si (KR); Hyun-Chul Ji, Yongin-si (KR); Won-Bok Lee, Yongin-si (KR); Hyuck-Keun Oh, Yongin-si (KR); Seung-Hee Jeong, Yongin-si (KR); Hideki Miyazaki, Yongin-si (KR)

Correspondence Address: CHRISTIE, PARKER & HALE, LLP, PO BOX 7068, PASADENA, CA, 91109-7068, US

(21) Appl. No.: 11/734,775

(22) Filed: Apr. 12, 2007

(30) Foreign Application Priority Data
Apr. 28, 2006 (KR) 10-2006-0038579

(51) Int. Cl. H01L 31/00

(52) U.S. Cl. 257/431

(57) ABSTRACT

An image display device includes a vacuum structure having a first substrate, a second substrate placed at the front side of the first substrate to form a first region together with the first substrate, and a reinforcing panel placed at the rear of the first substrate to form a second region together with the first substrate. An electron emission unit is provided on the first substrate, and a light emission unit is provided on the second substrate. The first substrate has at least one through-hole for communicating the first and the second regions with each other in the vacuum structure. The first and the second substrates have a sealing interface varied in width along the peripheries thereof.

### CROSS REFERENCE TO RELATED APPLICATION

The present application claims priority to and the benefit of Korean Patent Application No. 10-2006-0038579, filed on Apr. 28, 2006, in the Korean Intellectual Property Office, the entire content of which is incorporated herein by reference.

### BACKGROUND OF THE INVENTION

(a) Field of the Invention

The present invention relates to an image display device, and in particular, to an image display device having an improved vacuum structure.

(b) Description of Related Art

Generally, an image display device using electrons to emit light has an internal vacuum structure including electron emission regions and phosphor layers. The electrons emitted from the electron emission regions excite the phosphor layers, thereby emitting light and/or displaying the desired images.

Image display devices are classified, depending upon the electron source, into hot cathode types or cold cathode types. Furthermore, depending upon the shape of the vacuum structure, the image display devices are classified into bulb types, such as a cathode ray tube (CRT), or flat panel types with front and rear substrates and a sealing member, such as a vacuum fluorescent display (VFD) and a field emission array (FEA) type electron emission display.

With respect to flat panel type image display devices, the larger and higher the screen size and internal vacuum degree, the greater the pressure compressed thereto becomes. Accordingly, a plurality of spacers may be mounted within the vacuum structure to prevent distortion and/or fracture. The spacer may be located corresponding to a black layer disposed between the phosphor layers such that the spacer does not intrude the area of the phosphor layers.

However, since high resolution image display devices have been recently developed, the width of the black layer where the spacer is located has been narrowed, and correspondingly, spacers with a relatively small size and a high aspect ratio are required. However, manufacture of spacers satisfying such a condition and attaching thousands of tiny spacers to the front and/or the rear substrates is burdensome.

Furthermore, with the conventional image display device, the initial vacuum degree is not heightened due to the spacers, and a failure in mounting the spacers is likely during the exhausting process. If the image display device does not initially achieve a high vacuum, the vacuum degree is gradually lowered due to the outgassing of the members built in the vacuum structure, resulting in the display characteristic becoming deteriorated. Additionally, mount-failed spacers block the trajectories of electron beams, thereby deteriorating the screen image quality.

Moreover, with respect to the FEA type electron emission display, the spacers formed with a dielectric such as glass and ceramic may be struck with electrons during operation of the display, and surface-charged into a positive or negative potential. The charged spacers attract or repulse the electrons passing in the vicinity, thereby distorting the trajectories of electron beams, and deteriorating the display quality.

Accordingly, the spacers are effective in stabilizing the flat panel vacuum structure, but may deteriorate the display device productivity and the screen image quality.

If the practical image display area of the image display device is defined as an active area, the size and weight of the non-active area thereof should be reduced as much as possible to make the product lightweight and attractive to the consumer.

### SUMMARY OF THE INVENTION

In one exemplary embodiment of the present invention, there is provided an image display device which includes a vacuum structure. This vacuum structure is composed of a first substrate, a second substrate located on a first side of the first substrate to define with the first substrate a first region, and a reinforcing panel located on a second side of the first substrate to define with the first substrate a second region.

The image display device also includes an electron emission unit provided on the first substrate and a light emission unit provided on the second substrate. The electron emission unit further includes electron emission regions having cold cathode electron sources. The first substrate has at least one through-hole coupling the first region with the second region. This through hole is located between the electron emission unit and the sealing member substantially at the corners of the first substrate. The second substrate has a sidewall extending from the second substrate toward the first substrate, wherein the shape of the sidewall is substantially identical to the shape of the sealing member. The second substrate and the reinforcing panel are thicker than the first substrate.

A sealing interface is located between the first substrate and the second substrate. The sealing interface, which includes a sealing member interfacing the first and the second substrate, varies in width along peripheries of the first substrate and the second substrate. The sealing member has a maximum width at a center of sides of the first substrate and the second substrate, and a minimum width at corners of the first substrate and the second substrate. In addition, the sealing member has a substantially rectangular-shaped outer wall, and an inner wall narrowingly tapering from about a center of the sides of the first substrate and the second substrate toward a proximal corner of the first substrate and the second substrate. The sealing member comprises a support frame, a first frit layer disposed between the first substrate and the support frame, and a second frit layer disposed between the second substrate and the support frame. A further embodiment of the image display device is a glass frit which interfaces the sealing member with the first substrate and the second substrate.

### BRIEF DESCRIPTION OF THE DRAWINGS

FIG. 1 is an exploded perspective view of an image display device according to an exemplary embodiment of the present invention.

FIG. 2 is a cross sectional view of the image display device of FIG. 1.

FIG. 3 is a plan view of a first substrate and a sealing member of the image display device of FIG. 1.

FIG. 4 is a bottom view of a second substrate and a sealing member of the image display device of FIG. 1.

FIG. 5 is a cross sectional view of an image display device according to another exemplary embodiment of the present invention.

FIG. 6 is a partial exploded perspective view of first and second substrates of an image display device according to yet another exemplary embodiment of the present invention, applied to an FEA type electron emission display.

FIG. 7 is a partial sectional view of first and second substrates of an image display device according to still another embodiment of the present invention, applied to an FEA type electron emission display.

### DETAILED DESCRIPTION

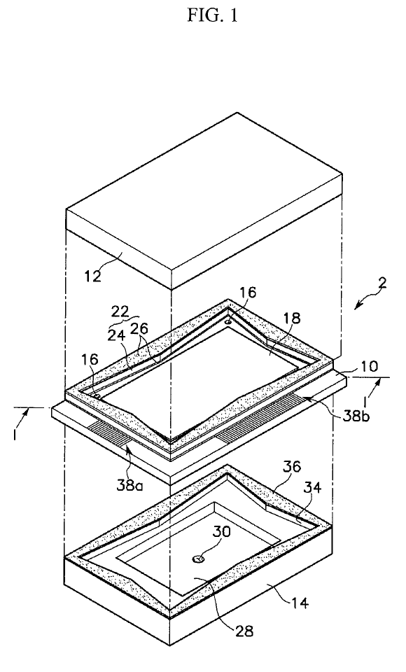

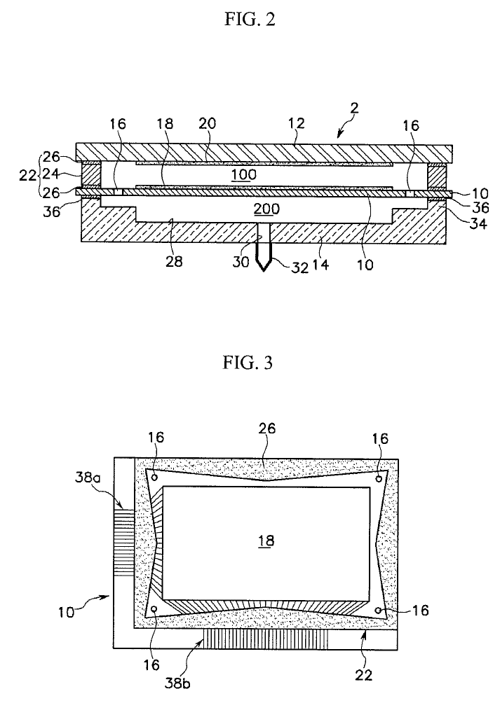

As shown in FIGS. 1 and 2, an image display device according to a first embodiment of the present invention is formed with a vacuum structure 2. The vacuum structure 2 includes first and second substrates 10, 12 aligned with each other having an interposed first region 100, and a reinforcing panel 14 attached to a rear of the first substrate 10 to form a second region 200.

The first and the second regions 100, 200 refer to spatial regions divided by the first substrate 10 within the vacuum structure 2. Through-holes 16 may be formed at the first substrate 10 to allow communication between the first and the second regions 100, 200.

An electron emission unit 18 is provided on a surface of the first substrate 10 facing the second substrate 12 to emit electrons toward the second substrate 12. A light emission unit 20 may be provided on a surface of the second substrate 12 facing the first substrate 10 to emit visible rays due to the electrons. The first substrate 10 and the electron emission unit 18 may form a cathode substrate, and the second substrate 12 and the light emission unit 20 may form an anode substrate.

A sealing member 22 may be placed at the periphery of the first and the second substrates 10, 12 to seal them to each other. The sealing member 22 may be formed with a glass frit, or with a pair of frit layers 26 disposed between the first substrate 10 and a support frame 24, and between the second substrate 12 and the support frame 24.

Accordingly, the first region 100 is surrounded by the first substrate 10, the second substrate 12, and the sealing member 22. The distance between the first and the second substrates 10, 12 is dependent on the height of the sealing member 22. The support frame 24 may be formed from the same material as the first and the second substrates 10, 12, or with a material having a similar thermal expansion coefficient as the first and the second substrates 10, 12.

In one exemplary embodiment, the second substrate 12 may be formed with a thickness adapted to endure vacuum pressure, for example, 10 mm or more. On the other hand, if vacuum pressure is not applied to the first substrate 10, the first substrate 10 may be formed with a thickness less than the second substrate 12, for example, with 5 mm or less.

The first substrate 10 may include various electrodes for controlling the activation of electron emission, the amount of electron emission, and the trajectories of electron beams. The first substrate 10 may endure several high temperature heat treatment processes during the formation of the electron emission regions, the electrodes and the inter-electrodes insulating layers. The first substrate 10 with a thickness of 5 mm or less suffers lower thermal stress even under extreme temperature variation which may prevent fracturing, while enhancing the layer formation characteristic of the electron emission unit 18.

The reinforcing panel 14 outlining the vacuum structure 2 may have a centrally disposed recessed portion 28 facing the first substrate 10 to provide a second region 200 enveloped by the first substrate 10 and the reinforcing panel 14. The reinforcing panel 14 may have a sidewall 34 at its periphery facing the first substrate 10 such that the recessed portion 28 is located within the sidewall 34. A frit layer 36 may be wholly or partially formed on a surface of the sidewall 34 facing the first substrate 10 to seal the first substrate 10 and the reinforcing panel 14 to each other.

If it will be subject to vacuum pressure, the reinforcing panel 14 may have a thickness greater than the first substrate 10. For example, the reinforcing panel 14 may have the same thickness as the second substrate 12. The reinforcing panel 14 may be provided with an exhaust vent 30 and an exhaust tube 32 for ventilating the interior of the structure, and a getter (not shown) for adsorbing remnant gas to heighten the vacuum degree.

As described above, the reinforcing panel 14 has a substantially flat shape along its periphery, and a centrally disposed recessed portion 28 facing the first substrate 10 to provide a second region 200 communicable with the first region 100. Accordingly, the distance between the first and the second substrates 10, 12 is constant absent the use of spacers in the first region 100, thereby obtaining a stable structure. Furthermore, the initial vacuum degree of the vacuum structure 2 is heightened due to the enlarged internal volume, compensating for the deterioration in vacuum degree due to outgassing. Furthermore, the non-active area of the vacuum structure 2 has a minimal size and weight. In view of the distribution of stress applied to the first substrate 10, the second substrate 12 and the reinforcing panel 14, the sealing member 22 and the sidewall 34 are spatially varied in width.

As shown in FIG. 3, the electron emission unit 18 may be located within an active area (i.e., the practical image display area) of the first substrate 10 to emit electrons, and the through-holes 16 and the sealing member 22 may be located at a non-active area external to the active area to allow communication between the first and the second regions 100, 200. The driving electrodes provided at the electron emission unit 18 are drawn to the periphery of the first substrate 10 to form electrode pad portions 38a, 38b external to the sealing member 22.

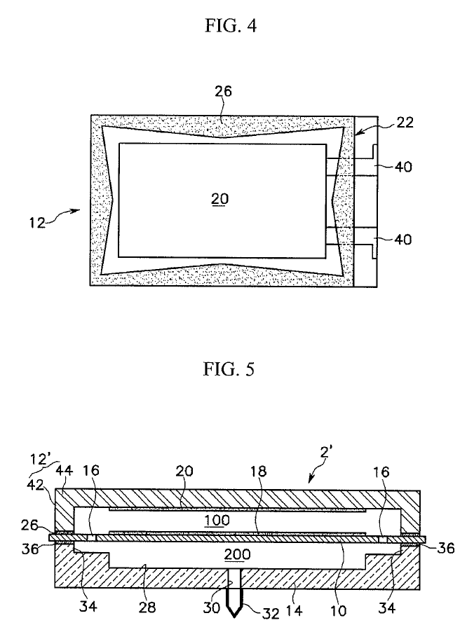

As shown in FIG. 4, the light emission unit 20 may be located within an active area of the second substrate 12, and the sealing member 22 may be located at the non-active area external to the active area. Lead lines 40 may be extended through the interior and the exterior of the sealing member 22 to apply a voltage to an electron accelerating electrode (also called the “anode electrode”) of the light emission unit 20.

After the vacuum structure is constructed, stress may be concentrated at the center of the sides of the first and the second substrates 10, 12, while stress may be relatively weak at the four diagonal corners thereof. Accordingly, the sealing member 22 disposed between the first and the second substrates 10, 12 may be widest at the center of the sides of the two substrates, and may be narrowest adjacent the diagonal corners of the two substrates.

More specifically, the sealing member 22 may be widest at the center of the sides of the first and the second substrates 10, 12, and may narrowingly taper toward the diagonal corners of the two substrates. The tapering of the sealing member 22 inhibits the extreme intensity variation along the periphery of the first and the second substrates 10, 12 and more uniformly distributes the stress on the two substrates. The sealing member 22 has an altered inner wall configuration while maintaining a rectangular outer wall configuration to satisfy the above-described width condition.

In order to more effectively use the non-active area, the through-holes 16 of the first substrate 10 may be located external to the diagonal corners of the active area. Accordingly, the sealing member 22 has a reduced outline size, but exerts excellent adhesion. Consequently, the size of the non-active area may be reduced, thereby decreasing the weight of the vacuum structure 2 significantly.

With further reference to FIG. 1, the sidewall 34 of the reinforcing panel 14 may bear the same shape as the sealing member 22 in consideration of the stress distribution of the first substrate 10 and the reinforcing panel 14. More specifically, the sidewall 34 has a maximum width adjacent the center of the sides of the first substrate 10 and the reinforcing panel 14, and a minimum width at the diagonal corners of the first substrate 10 and the reinforcing panel 14.

In another exemplary embodiment as shown in FIG. 5, the second substrate 12′ may have a sidewall 42 extending from the periphery thereof toward the first substrate 10. In other words, the second substrate 12′ has a flat portion 44 parallel to the first substrate 10, and a sidewall 42 placed at the periphery of the flat portion 44. A frit layer 26 may be provided between the sidewall 42 and the first substrate 10 to seal the first and the second substrates 10, 12′ to each other.

Similar to the sealing member 22, the sidewall 42 of the second substrate 12′ has a maximum width adjacent the center of the sides of the first and the second substrates 10, 12′, and a minimum width at the diagonal corners of the first and the second substrates 10, 12′.

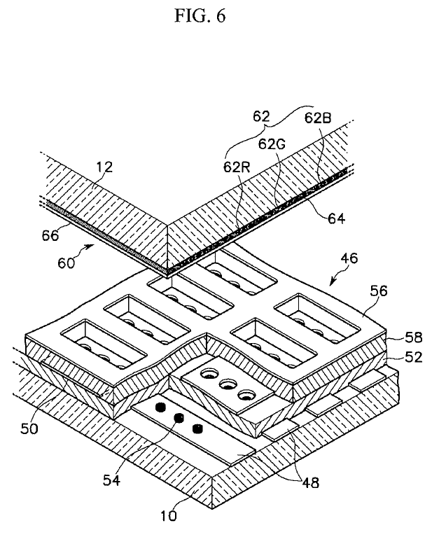

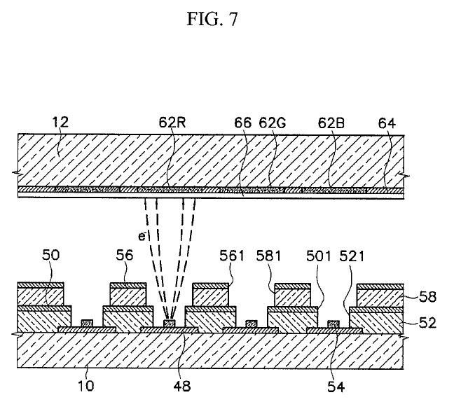

The above-described vacuum structure 2, 2′ is well-adapted for use in manufacturing image display devices using cold cathodes as the electron emission sources, such as an FEA type electron emission display or an SCE type electron emission display. The image display device applied to the FEA type will be briefly explained with reference to FIGS. 6 and 7.

As shown in FIGS. 6 and 7, the electron emission unit 46 provided at the first substrate 10 includes cathode and gate electrodes 48, 50 as the driving electrodes, a first insulating layer 52 disposed between the cathode and the gate electrodes 48, 50 to insulate the electrodes from each other, electron emission regions 54 electrically connected to the cathode electrodes 48, a focusing electrode 56 placed over the gate electrodes 50, and a second insulating layer 58 disposed between the gate electrodes 50 and the focusing electrode 56 to insulate the electrodes from each other.

The first insulating layer 52 and the gate electrodes 50 have openings 521, 501 adapted to expose respective electron emission regions 54. The second insulating layer 58 and the focusing electrode 56 may have openings 581, 561 formed at respective crossing regions of each cathode and the gate electrode 48, 50.

The electron emission regions 54 may be formed with a material emitting electrons when an electric field is applied thereto under a vacuum atmosphere, such as a carbonaceous material and a nanometer-sized material. For instance, the electron emission regions 54 may be formed with carbon nanotube, graphite, graphite nanofiber, diamond, diamond-like carbon, C₆₀, silicon nanowire, or a combination thereof. Alternatively, the electron emission regions may be formed with a sharp-pointed tip structure primarily based on molybdenum Mo or silicon Si.

The light emission unit 60 provided at the second substrate 12 may include red, green and blue phosphor layers 62R, 62G and 62B, black layers 64 disposed between the respective phosphor layers 62 to enhance the screen contrast, and an anode electrode 66 formed on the phosphor layers 62 and the black layers 64. The anode electrode 66 may be formed with a metallic material such as aluminum. The anode electrode 66 reflects the visible rays radiated from the phosphor layers 62 to the first substrate 10 toward the second substrate 12 to thereby enhance the screen luminance.

The above-structured image display device may be driven by supplying outside voltage to the cathode electrodes 48, the gate electrodes 50, the focusing electrode 56 and the anode electrode 66. For instance, one of the cathode electrodes 48 and one of the gate electrodes 50 may receive a scan driving voltage, and the other electrode may receive a data driving voltage. The focusing electrode 56 receives a voltage required for focusing the electron beams, for instance, a 0V ground voltage or a negative direct current voltage of several to several tens volts. The anode electrode 66 receives a voltage required for accelerating the electron beams, for instance, a positive direct current voltage of several hundreds to several thousands volts.

Electric fields are then formed around the electron emission regions 54 at the pixels where the voltage difference between the cathode and the gate electrodes 48, 50 exceeds the threshold value, and electrons are emitted from those electron emission regions 54. The emitted electrons pass through the openings 561 of the focusing electrode 56, and are focused at the center of the bundles of electron beams. The electrons are attracted by the high voltage applied to the anode electrode 66, thereby colliding against the phosphor layers 62 at the relevant pixels and exciting them to emit light.

As described above, with respect to exemplary embodiments of the image display device of the present invention, the non-active area is efficiently used due to the shape of the sealing member sidewall and the reinforcing panel. Consequently, the weight of the display device product can be significantly reduced.

The structure above is described according to an exemplary embodiment of the present invention is applied to the FEA type electron emission display, but not limited thereto. That is, such a structure may be applied to other image display devices in addition to the FEA type electron emission display.

Although exemplary embodiments of the present invention have been described in detail hereinabove, it will be understood by one of ordinary skill in the art that many variations and/or modifications of the basic inventive concept taught herein will still fall within the spirit and scope of the present invention, as defined in the appended claims.

What is claimed is:

1. An image display device comprising:
a vacuum structure including a first substrate, a second substrate located on a first side of the first substrate to define with the first substrate a first region, and a reinforcing panel located on a second side of the first substrate to define with the first substrate a second region;
an electron emission unit provided on the first substrate; and
a light emission unit provided on the second substrate;
wherein the first substrate has at least one through-hole coupling the first region with the second region; and
wherein a sealing interface is located between the first substrate and the second substrate, the sealing interface varying in width along peripheries of the first substrate and the second substrate.

2. The image display device of claim 1, wherein the sealing interface includes a sealing member interfacing the first substrate and the second substrate, the sealing member varying in width along the peripheries of the first substrate and the second substrate.

3. The image display device of claim 2, wherein the sealing member has a maximum width at a center of sides of the first substrate and the second substrate, and a minimum width at corners of the first substrate and the second substrate.

4. The image display device of claim 3, wherein the sealing member has a substantially rectangular-shaped outer wall, and an inner wall narrowingly tapering from about a center of the sides of the first substrate and the second substrate toward a proximal corner of the first substrate and the second substrate.

5. The image display device of claim 4, wherein the through-hole of the first substrate is located between the electron emission unit and the sealing member substantially at the corners of the first substrate.

6. The image display device of claim 2, wherein a glass frit interfaces the sealing member with the first substrate and the second substrate.

7. The image display device of claim 2, wherein the sealing member comprises a support frame, a first frit layer disposed between the first substrate and the support frame, and a second frit layer disposed between the second substrate and the support frame.

8. The image display device of claim 1, the second substrate having a sidewall extending from the second substrate toward the first substrate, wherein a shape of the sidewall is substantially identical to the shape of the sealing interface.

9. The image display device of claim 1, wherein a sealing interface is located between the first substrate and the reinforcing panel, the sealing interface varying in width along the peripheries of the first substrate and the reinforcing panel.

10. The image display device of claim 9, wherein the reinforcing panel has a recessed portion, the recessed portion having a peripheral sidewall,
wherein the peripheral sidewall varies in width along the peripheries of the first substrate and the second substrate.

11. The image display device of claim 10, wherein the peripheral sidewall has a maximum width at a center of sides of the reinforcing panel, and a minimum width at corners of the reinforcing panel.

12. The image display device of claim 11, wherein an outer edge of the peripheral sidewall is substantially rectangular and an inner edge of the peripheral sidewall narrowingly tapers from the center of the sides of the reinforcing panel toward the corners of the reinforcing panel.

13. The image display device of claim 1, wherein the second substrate and the reinforcing panel are thicker than the first substrate.

14. The image display device of claim 1, wherein the electron emission unit further includes electron emission regions having cold cathode electron sources.
